(19) United States
(12) Patent Application Publication
(10) Pub. No.: US 2022/0154517 A1
(43) Pub. Date: May 19, 2022

(54) SWITCH DEVICE

(71) Applicant: KABUSHIKI KAISHA TOKAI RIKA DENKI SEISAKUSHO, Aichi (JP)

(72) Inventor: Yutaro ITO, Aichi (JP)

(21) Appl. No.: 17/426,020

(22) PCT Filed: Jan. 24, 2020
(86) PCT No.: PCT/JP2020/002580

§ 371 Date: Jul. 27, 2021

(30) Foreign Application Priority Data
Feb. 1, 2019 (JP) 2019-016714

(51) Int. Cl. E05F 15/695; B60R 16/02; H01H 25/00; H01H 23/00; B60J 1/17

(52) U.S. Cl. CPC E05F 15/695; B60R 16/02; E05Y 2900/55; H01H 23/00; B60J 1/17; H01H 25/00

(57) ABSTRACT

A switch device includes an operating knob to receive switch operations for plural devices to be controlled, a detection unit attached to the operating knob to detect an operation position on the operating knob, a housing displaceably supporting the operating knob, and a control unit to control at least one of the plural devices to be controlled in response to the operation position detected by the detection unit. The control unit identifies the at least one device to be controlled in response to a displacement state of the operating knob.

### CROSS-REFERENCES TO RELATED APPLICATIONS

The present patent application claims the priority of Japanese patent application No. 2019/016714 filed on Feb. 1, 2019, and the entire contents of Japanese patent application No. 2019/016714 are hereby incorporated by reference.

### TECHNICAL FIELD

The present invention relates to a switch device.

### BACKGROUND ART

A vehicle power window switch is known which is used for opening and closing windows of a vehicle (see, e.g., Patent Literature 1).

The vehicle power window switch of Patent Literature 1 has an operating knob to be operated by an operation-performing body, a housing supporting the operating knob, electrodes provided inside the operating knob to sense contact of the operation-performing body, and a control unit that is connected to the electrodes and detests contact of the operation-performing body with the operating knob based on changes in capacitances of the electrodes. Two electrodes corresponding to right and left windows are attached to the operating knob. An operating knob to operate rear-side windows of the vehicle is also provided.

### CITATION LIST

### Patent Literature

Patent Literature 1: JP 2015/109212 A

### SUMMARY OF INVENTION

### Technical Problem

The vehicle power window switch disclosed in Patent Literature 1 may cause a problem that it is not possible to sufficiently save space in the switch device since it is necessary to provide the operating knob for operating the left and right windows and that for the left and rear right-side windows. That is, there is a demand for further downsizing the switch device.

It is an object of the invention to further downsize the switch device.

### Solution to Problem

According to an embodiment of the invention, a switch device according to [1] to [10] below is provided.

[1] A switch device, comprising:
an operating knob to receive switch operations for a plurality of devices to be controlled;
a detection unit attached to the operating knob to detect an operation position on the operating knob;
a housing displaceably supporting the operating knob; and
a control unit to control at least one of the plurality of devices to be controlled in response to the operation position detected by the detection unit,
wherein the control unit identifies the at least one device to be controlled in response to a displacement state of the operating knob.

[2] The switch device as defined in [1], wherein the detection unit comprises sensing portions arranged respectively at a plurality of locations on the single operating knob to detect contact or proximity of a human body.

[3] The input device as defined in [2], wherein the sensing portions are arranged so as to detect contact or proximity to at least both end portions in a direction intersecting a displacement direction of the operating knob.

[4] The switch device as defined in [3], wherein the sensing portion is arranged so as to detect contact or proximity to a central portion in the direction intersecting the displacement direction of the operating knob.

[5] The switch device as defined in any one of [2] to [4], wherein the sensing portion comprises a detection electrode to detect capacitance.

[6] The switch device as defined in any one of [1] to [4], wherein the switch device is mounted on a vehicle, the position of the operating knob can be moved in a rearward direction of the vehicle, and the control unit controls at least one of the plurality of devices to be controlled in response to the position of the operating knob.

[7] The switch device as defined in [6], wherein movement of the operating knob is locked in a state in which the position thereof is moved in the rearward direction of the vehicle.

[8] The switch device as defined in [7], wherein the operating knob is unlocked when a predetermined period of time elapses or a predetermined operation is performed on the sensing portion after being locked in a state in which the position thereof is moved in the rearward direction of the vehicle.

[9] The switch device as defined in [7] or [8], comprising:
a solenoid actuator as a mechanism to lock or unlock movement of the operating knob.

[10] The switch device as defined in [4], wherein the control unit controls all the devices to be controlled when contact or proximity to the central portion in the direction intersecting the displacement direction of the operating knob is detected.

### Advantageous Effects of Invention

According to an embodiment of the invention, a switch device can be provided that is further downsized.

### BRIEF DESCRIPTION OF DRAWINGS

FIG. 1 is a perspective view showing the vicinity of a driver's seat when a switch device in an embodiment of the present invention is mounted on an armrest of the driver side door of a vehicle.

FIG. 2A is a top plan view showing the switch device in the embodiment of the invention.

FIG. 2B is a cross sectional view of the switch device taken along a line A-A in FIG. 2A.

FIG. 3 is a block diagram illustrating a configuration of the switch device in the embodiment of the invention.

FIG. 4A is an explanatory diagram illustrating the initial state of the switch device during an operation of the switch device in the embodiment of the invention.

FIG. 4B is an explanatory diagram illustrating a motion of a switch operation according to the embodiment of the invention when moving a position of a housing (an operating knob) in a rearward direction by a finger.

FIG. 4C is an explanatory diagram illustrating a motion of the switch operation in the embodiment of the invention when pulling up the operating knob by a finger.

FIG. 4D is an explanatory diagram illustrating a motion of the switch operation in the embodiment of the invention when the position of the housing (the operating knob) returns to the initial state.

FIG. 5 is an explanatory flowchart showing the operation of the switch device in the embodiment of the invention.

### DESCRIPTION OF EMBODIMENTS

### Embodiment

A switch device 1 in the embodiment of the invention has an operating knob 10 to receive switch operations for plural devices to be controlled, detection electrodes (20R, 20C, 20L) as a detection unit attached to the operating knob 10 to detect an operation position on the operating knob 10, a housing 30 displaceably supporting the operating knob 10, and a control unit 60 to control at least one of the plural devices to be controlled in response to the operation position detected by the detection electrodes (20R, 20C, 20L), and it is configured such that the control unit 60 identifies the at least one device to be controlled in response to a displacement state of the operating knob 10.

The switch device 1 is mounted on a vehicle 100, can acts as a switch to receive operations for devices to be controlled, and is applicable to various devices. In the present embodiment described below, it is mounted on the vehicle 100 and the devices to be controlled are, e.g., window regulators.

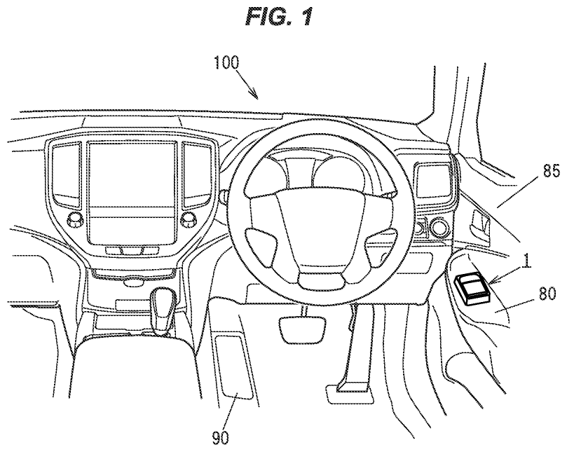

The switch device 1 is mounted on an armrest 80 of a driver side door 85 of the vehicle 100 as shown in FIG. 1 and is to open/close front-side and rear-side windows of the vehicle by controlling the window regulators. The switch device 1 includes sensing portions on the operating knob 10, and the detection electrodes (20R, 20L) to detect capacitance for detecting the operation position (right window, left window) are provided on the sensing portions. It is also configured so that opening/closing control of rear-side windows is performed in a state in which a position of the housing 30 supporting the operating knob 10 is moved in a rearward direction of the vehicle and the position has been moved in the rearward direction. Since the opening/closing operation of the right and left windows on the front and rear sides can be performed by the single operating knob 10, it is possible to further reduce the size of the switch device.

In the configuration of the present embodiment described below, detection electrodes to detect contact or proximity to both end portions in a direction intersecting a displacement direction of the operating knob and a detection electrode to detect contact or proximity to a central portion in the direction intersecting the displacement direction of the operating knob are provided as the sensing portions to detect contact or proximity of a human body.

(The Operating Knob 10)

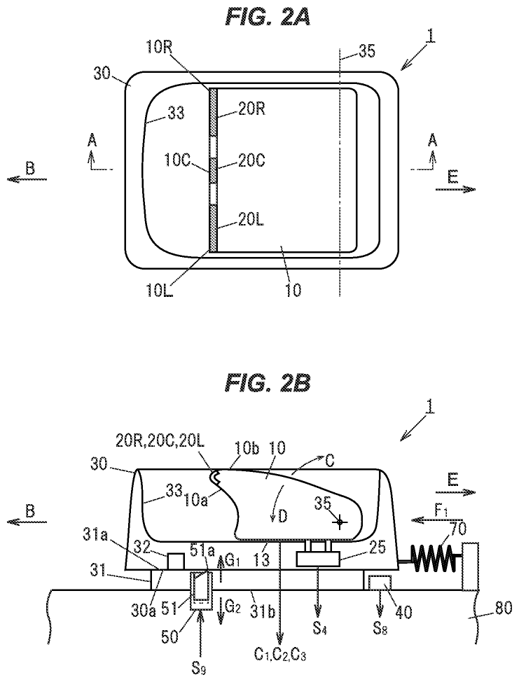

As shown in FIGS. 2A and 2B, the operating knob 10 is housed in a recessed portion 33 of the housing 30 and is rotatably supported by a rotating shaft 35. The operating knob 10 is to operate a driver side window, a front passenger side window and rear-side windows in response to the detection result from the sensing portions and the displacement state of the operating knob 10 (the housing 30).

Since the operating knob 10 is supported so as to be rotatable relative to the housing 30, the displacement state of the operating knob 10 in a front-rear direction of the vehicle is the same as that of the housing 30. Therefore, in the following description, the device to be controlled is identified in response to the displacement state of the housing 30, and the front-side (driver side, front passenger side) windows and rear-side windows are controlled.

In the present embodiment, it is mounted so that a direction B shown in FIGS. 2A and 2B coincides with a forward direction of the vehicle.

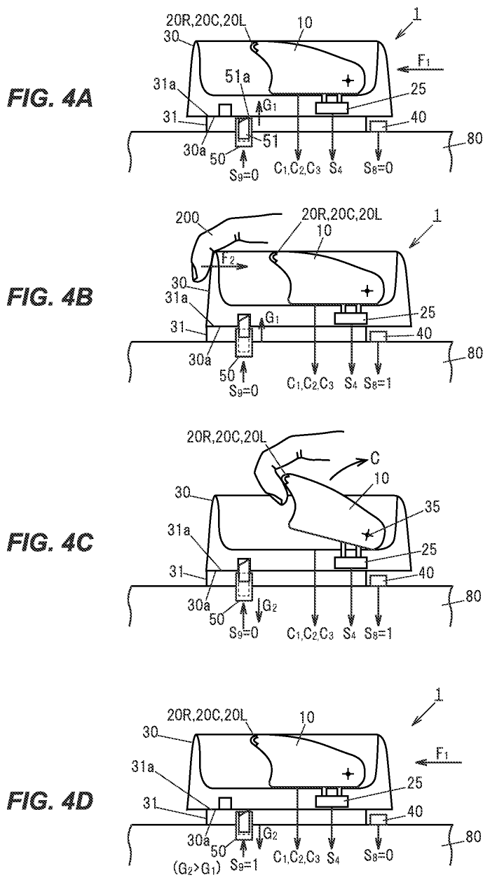

As shown in FIGS. 2B and 4C, a recessed operation surface 10a to facilitate a pull-up operation of the operating knob by a finger 200 is formed on a front surface of the operating knob 10 (a surface facing in the direction B). It is thus easy to perform the pull-up operation in a direction C about the rotating shaft 35 shown in FIG. 4C.

Meanwhile, a pressing operation surface 10b to facilitate a push-down operation of the operating knob by the finger 200 is formed on an upper surface of the operating knob 10 (a surface facing in an upward direction of the vehicle), as shown in FIG. 2B. It is thus easy to perform the push-down operation in a direction D about the rotating shaft 35.

A lower portion 13 of the operating knob 10 is a detection portion where a knob operation amount detection sensor 25 detects an operation amount of the operating knob 10. By the pull-up operation or push-down operation as described above, the lower portion 13 of operating knob 10 moves relative to the knob operation amount detection sensor 25. It is thus possible to detect the operation amount and operation direction of the operating knob 10.

(The Detection Electrodes 20R, 20C, 20L)

The switch device 1 includes the sensing portions each arranged along a direction intersecting an operation receiving direction to detect contact or proximity of a human body. In the present embodiment, the sensing portions are detection electrodes as the detection unit to detect the operation position on the operating knob 10 and are the detection electrodes (20R, 20C, 20L) that detect capacitance. The detection electrodes (20R, 20C, 20L) detect capacitance values C₁, C₂, C₃, which change due to contact or proximity of a finger, etc., of an operator, and output them to the control unit 60.

As the detection electrodes to detect contact or proximity to both end portions in a direction intersecting the displacement direction of the operating knob 10 (a direction E), the detection electrode 20R is attached on a right end side 10R of the operating knob 10 and the detection electrode 20L is attached on a left end side 10L of the operating knob 10, as shown in FIGS. 2A and 2B.

Meanwhile, as the detection electrode to detect contact or proximity to the central portion in the direction intersecting the displacement direction of the operating knob 10 (the direction E), the detection electrode 20C is attached to a central portion 10C of the operating knob 10, as shown in FIGS. 2A and 2B.

All the detection electrodes (20R, 20C, 20L) are attached in such a manner that at least a part of the finger 200 comes into contact therewith or comes close thereto when the pull-up operation shown in FIG. 4C or the push-down operation is performed.

(The Knob Operation Amount Detection Sensor 25)

As shown in FIG. 2B, the knob operation amount detection sensor 25 is provided at a lower portion of the housing 30 to detect the operation amount of the operating knob 10. The knob operation amount detection sensor 25 only needs to be a sensor that detects the pull-up operation amount and the push-down operation amount of the operating knob 10.

The knob operation amount detection sensor 25 may be a switch that outputs ON and OFF signals respectively by a pull-up operation and a push-down operation of the operating knob 10. Alternatively, the knob operation amount detection sensor 25 may be a detection sensor that outputs an analog output and a digital output in response to the pull-up operation amount and the push-down operation amount of the operating knob 10. The knob operation amount detection sensor 25 can be a switch or a detection sensor that outputs a signal required by the window regulator.

(The Housing 30)

The housing 30 houses and rotatably supports the operating knob 10 in the recessed portion 33, as shown in FIG. 2B, etc. In addition, the housing 30 includes the knob operation amount detection sensor 25.

As shown in FIG. 1, the housing 30 is mounted on the armrest 80 of the driver side door 85 of the vehicle 100. The housing 30 can alternatively be mounted on a floor console 90 shown in FIG. 1. Mounting the housing 30, i.e., the switch device 1, on the floor console 90 has an effect that, e.g., a harness for wiring can be shorter or it is possible to operate also from the front passenger seat side.

The housing 30 is mounted on the armrest 80 via a slide base 31, as shown in FIG. 2B. A lower side 31b of the slide base 31 is fixed to the armrest 80, and an upper side 31a of the slide base 31 slidably supports a lower surface 30a of the housing 30. This allows the housing 30 to be slidingly displaced toward the rear side of the vehicle 100 (in the direction E).

As shown in FIG. 2B, a spring 70 is attached between the housing 30 and the slide base 31 or the armrest 80, and the housing 30 is biased toward the front side of the vehicle (in the direction B) by a predetermined biasing force F₁ in the initial state.

(A Displacement State Detection Sensor 40)

A displacement state detection sensor 40 is a detector to detect a state of displacement of the housing 30 (the operating knob 10) toward the rear side (in the direction E). The displacement state detection sensor 40 detects the initial state shown in FIG. 4A and the rearwardly displaced state shown in FIG. 4C. As the displacement state detection sensor 40, it is possible to use, e.g., a limit switch which comes into contact with a portion of housing 30 and detects the position of that portion, or an optical position sensor which detects a change in light emitted onto a portion of housing 30 and detects the position of that portion, as an example.

When the housing 30 (the operating knob 10) is in the initial state and is located on the front side (the direction B), the displacement state detection sensor 40 outputs, e.g., an output S₈=0. On the other hand, when the housing 30 (the operating knob 10) is located on the rear side (the direction E), an output S₈=1 is output. In this regard, displacement of the housing 30 is locked (described later) when the output S₈=1 is output.

(A Locking Solenoid 50)

A locking solenoid 50 is to lock the housing 30 in the rearwardly displaced state. The housing 30 is biased with the predetermined biasing force F₁ toward the front side of the vehicle (in the direction B) by the spring 70, as described above. The locking solenoid 50 is used to lock the rearwardly displaced housing 30 when the housing 30 is displaced toward the rear side (in the direction E) by the finger 200 as shown in FIG. 4B. As a result, it is easy to pull up or push down the operating knob 10 in the state in which the housing 30 (the operating knob 10) is located on the rear side (the direction E).

The locking solenoid 50 shown in FIG. 2B is configured such that a movable iron core (plunger) 51 can move in a direction G₁ and a direction G₂ shown in FIG. 2B by means of an electromagnetic mechanism (not shown) provided inside the locking solenoid 50.

(Operation of the Locking Solenoid 50 when not Energized)

The control unit 60 drives the locking solenoid 50 based on a control signal S₉. The locking solenoid 50 is not energized, except when unlocking the housing 30 in the state in which the housing 30 is rearwardly displaced. Here, the movable iron core 51 is biased toward the housing 30 in the direction G₁ shown in FIG. 2B by a spring (not shown). Therefore, when the locking solenoid 50 is not energized, a biasing force in the direction G₁ is constantly applied to the movable iron core 51.

Since the movable iron core 51 is biased in the direction G₁ as shown in FIG. 2B when the locking solenoid 50 is not energized, a tip 51a of the movable iron core 51 butts against the lower surface 30a of the housing 30 with a predetermined biasing force. In this state, the housing 30 can be slidingly displaced toward the rear side of the vehicle (the direction E) and the front side (the direction B) shown in FIGS. 2A and 2B.

When the housing 30 is displaced toward the rear side (the direction E) by the finger 200 with a rearward pulling force F₂ as shown in FIG. 4B, the movable iron core 51 fits at a predetermined lock position into a locking hole 32 provided on the lower surface 30a of the housing 30.

(Operation of the Locking Solenoid 50 when Energized)

The control unit 60 drives the locking solenoid 50 based on the control signal S₉. The locking solenoid 50 is energized when unlocking the housing 30 in the state in which the housing 30 is rearwardly displaced.

In the locking solenoid 50, when the electromagnetic mechanism (not shown) is energized, the movable iron core 51 is electromagnetically attracted toward the inside of the solenoid and moves in the direction G₂ shown in FIG. 4C. As a result, the movable iron core 51 is withdrawn from the locking hole 32, and the housing 30 in the rearwardly displaced state is unlocked. The housing 30 returns to the initial state (the initial position) shown in FIG. 4A by the biasing force F₁, as shown in FIG. 4D.

(The Control Unit 60)

The control unit 60 receives an input signal, then outputs a control signal S₁₀ according to a predetermined program, and thereby controls opening/closing of the windows of the vehicle via the window regulators. The control unit 60 includes, e.g., a microcomputer composed of a CPU (Central Processing Unit) performing calculation and processing, etc., of the acquired data according to a stored program, and a RAM (Random Access Memory) and a ROM (Read Only Memory) as semiconductor memories, etc. A current driver, etc., to drive the window regulator can also be provided.

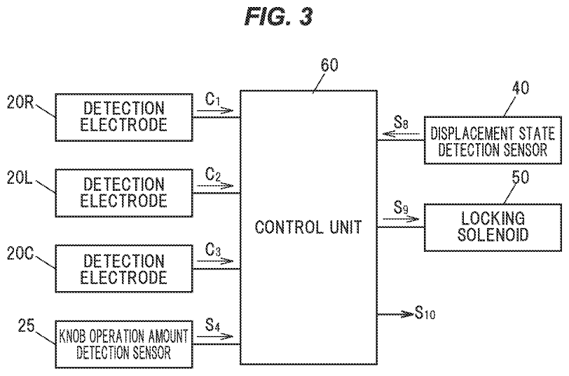

As shown in FIG. 3, the control unit 60 is connected to the detection electrodes (20R, 20C, 20L) to receive input of the respective electrode capacitance values C₁, C₂, C₃ detected by the detection electrodes (20R, 20C, 20L). It is also connected to the knob operation amount detection sensor 25 to receive input of detection information S₈ about a pull-up operation or a push-down operation of the operating knob 10. In addition, the control signal S₉ is output according to a predetermined program to control the operation of the locking solenoid 50. In addition, the control signal S₁₀ is calculated and output to the device to be controlled.

The detection information S₈ from the knob operation amount detection sensor 25 is S₈=0 when the housing 30 is in the initial state (the initial position) shown in FIG. 4A, and S₈=1 when the rearwardly displaced housing 30 is in the locked state (the lock position) shown in FIG. 4B. The control signal S₉ to the locking solenoid 50 is S₉=1 when unlocking, and otherwise S₉=0.

(Operation of the Switch Device 1)

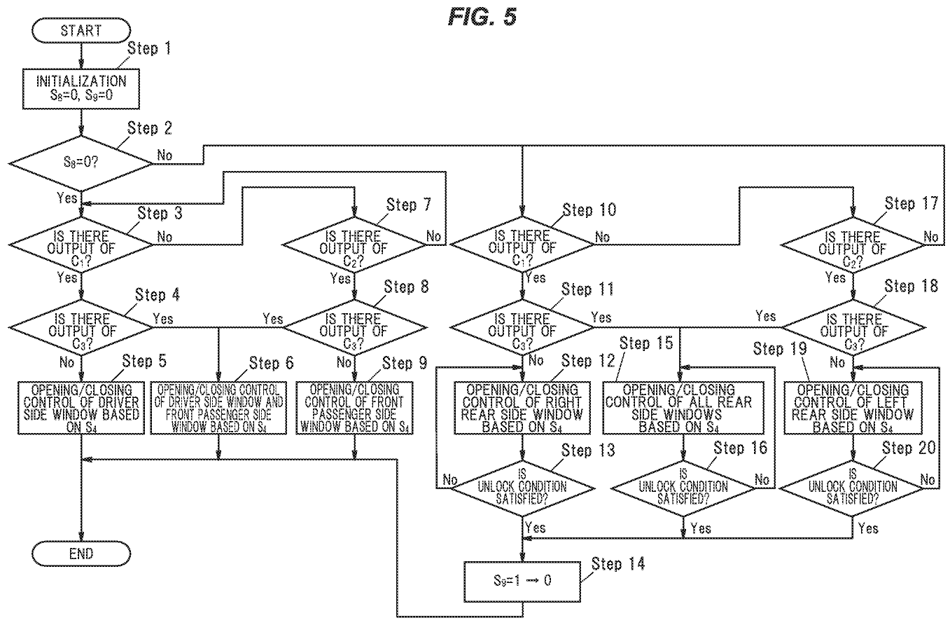

The operation of the switch device 1 will be described with the flowchart of the switch device in the embodiment shown in FIG. 5 while referring to the displacement state of the housing 30 in reference to FIGS. 4A to 4D.

(Step 1)

Firstly, the control unit 60 initializes the detection information S₈ from the knob operation amount detection sensor 25 and the control signal S₉ to the locking solenoid 50. In other words, the detection information S₈ is reset to 0 and the control signal S₉ to 0. Thus, the position of the housing (the operating knob) is in the initial state shown in FIG. 4A.

(Step 2)

The control unit 60 determines whether the detection information S₈ from the displacement state detection sensor 40 is S₈=0. The process proceeds to Step 3 when it is S₈=0 (Step 2: Yes), and the process proceeds to Step 10 when it is not S₈=0 (Step 2: No).

(Step 3)

Since the detection information S₈ from the displacement state detection sensor 40 is S₈=0, the housing 30 is in the initial state (the initial position). Therefore, the control unit 60 identifies the device to be controlled, in response to this displacement state of the housing 30. That is, the control unit 60 controls the front side (driver side, front passenger side) windows of the vehicle 100.

Based on the capacitance value C₁ input from the detection electrode 20R, the control unit 60 determines whether the detection electrode 20R is ON. The control unit 60 has, e.g., a predetermined threshold Cth for determining contact or proximity of a finger, etc., to the detection electrode. The control unit 60 can determine that the detection electrode 20R is ON, i.e., an operation has been performed on the operation position to which the detection electrode 20R is attached (the driver side window), by comparing the capacitance value C₁ with the Cth. The process proceeds to Step 4 when the detection electrode 20R is ON (Step 3: Yes), and the process proceeds to Step 7 when the detection electrode 20R is not ON (Step 3: No).

(Step 4)

Based on the capacitance value C₃ input from the detection electrode 20C, the control unit 60 determines whether the detection electrode 20C is ON. The control unit 60 can determine whether the detection electrode 20R is ON, by comparing the capacitance value C₃ with the Cth. The process proceeds to Step 6 when the detection electrode 20C is ON (Step 4: Yes), and the process proceeds to Step 5 when the detection electrode 20C is not ON (Step 4: No).

(Step 5)

The control unit 60 controls opening/closing of the window of the vehicle via the window regulator by outputting the control signal S₁₀ based on the detection information S₄ about the pull-up operation or push-down operation of the operating knob 10. That is, the operation position is identified by the detection electrode, and an opening operation or a closing operation of the window corresponding to the operation position (driver side, front passenger side, rear right-side, rear left-side) is controlled based on the detection information S₄. In Step 5, the control unit 60 controls the opening operation or closing operation of the driver side window.

(Step 6)

The control unit 60 controls opening/closing of the window of the vehicle via the window regulator by outputting the control signal S₁₀ based on the detection information S₄ about the pull-up operation or push-down operation of the operating knob 10. That is, the operation position is identified by the detection electrode, and an opening operation or a closing operation of the window corresponding to the operation position (driver side, front passenger side, rear right-side, rear left-side) is controlled based on the detection information S₄. In Step 6, the control unit 60 controls the opening operation or closing operation of the driver side and front passenger side windows.

(Step 7)

Based on the capacitance value C₂ input from the detection electrode 20L, the control unit 60 determines whether the detection electrode 20L is ON. The control unit 60 can determine whether the detection electrode 20L is ON, by comparing the capacitance value C₂ with the Cth. The process proceeds to Step 8 when the detection electrode 20L is ON (Step 7: Yes), and the process returns to Step 3 when the detection electrode 20L is not ON

(Step 7: No).

(Step 8)

Based on the capacitance value C₃ input from the detection electrode 20C, the control unit 60 determines whether the detection electrode 20C is ON. The control unit 60 can determine whether the detection electrode 20C is ON, by comparing the capacitance value C₃ with the Cₜₕ. The process proceeds to Step 6 when the detection electrode 20C is ON (Step 8: Yes), and the process proceeds to Step 9 when the detection electrode 20C is not ON (Step 8: No).

(Step 9)

The control unit 60 controls opening/closing of the window of the vehicle via the window regulator by outputting the control signal S₁₀ based on the detection information S₄ about the pull-up operation or push-down operation of the operating knob 10. That is, the operation position is identified by the detection electrode, and an opening operation or a closing operation of the window corresponding to the operation position (driver side, front passenger side, rear right-side, rear left-side) is controlled based on the detection information S₄. In Step 9, the control unit 60 controls the opening operation or closing operation of the front passenger side window.

(Step 10)

Since the detection information S₈ from the displacement state detection sensor 40 is S₈=1, the housing 30 is in the locked state (the lock position). Therefore, the control unit 60 identifies the device to be controlled, in response to this displacement state of the housing 30. That is, the control unit 60 controls the rear-side (rear right-side, rear left-side) windows of the vehicle 100.

Based on the capacitance value C₁ input from the detection electrode 20R, the control unit 60 determines whether the detection electrode 20R is ON. The control unit 60 can determine that the detection electrode 20R is ON, i.e., an operation has been performed on the operation position to which the detection electrode 20R is attached (the rear right-side window), by comparing the capacitance value C₁ with the Cth. The process proceeds to Step 11 when the detection electrode 20R is ON (Step 10: Yes), and the process proceeds to Step 17 when the detection electrode 20R is not ON (Step 10: No).

(Step 11)

Based on the capacitance value C₃ input from the detection electrode 20C, the control unit 60 determines whether the detection electrode 20C is ON. The control unit 60 can determine whether the detection electrode 20C is ON, by comparing the capacitance value C₃ with the Cth. The process proceeds to Step 15 when the detection electrode 20C is ON (Step 11: Yes), and the process proceeds to Step 12 when the detection electrode 20C is not ON (Step 11: No).

(Step 12)

The control unit 60 controls opening/closing of the window of the vehicle via the window regulator by outputting the control signal S₁₀ based on the detection information S₄ about the pull-up operation or push-down operation of the operating knob 10. That is, the operation position is identified by the detection electrode, and an opening operation or a closing operation of the window corresponding to the operation position (driver side, front passenger side, rear right-side, rear left-side) is controlled based on the detection information S₄. In Step 12, the control unit 60 controls the opening operation or closing operation of the rear right-side window.

(Step 13)

The control unit 60 determines whether a condition for unlocking the housing 30 is satisfied. The unlocking condition is, e.g., whether a predetermined period of time has elapsed since the housing 30 was locked. A specific operation such as a double tap or a tracing operation on the detection electrode can be also set as the unlocking condition. The process proceeds to Step 14 when the unlocking condition is satisfied (Step 13: Yes), and the process returns to Step 12 when the unlocking condition is not satisfied (Step 13: No).

(Step 14)

The control unit 60 sets the control signal S₉ to the locking solenoid 50 to S₉=1 and energizes the locking solenoid 50. The movable iron core 51 is thereby withdrawn from the locking hole 32, and the housing 30 in the rearwardly displaced state is unlocked. The housing 30 returns to the initial state (the initial position) shown in FIG. 4A by the biasing force F₁, as shown in FIG. 4D. After unlocking, the control signal S₉ to the locking solenoid 50 is set to S₉=0 to bring the locking solenoid 50 into a non-energized state.

(Step 15)

The control unit 60 controls opening/closing of the window of the vehicle via the window regulator by outputting the control signal S₁₀ based on the detection information S₄ about the pull-up operation or push-down operation of the operating knob 10. That is, the operation position is identified by the detection electrode, and an opening operation or a closing operation of the window corresponding to the operation position (driver side, front passenger side, rear right-side, rear left-side) is controlled based on the detection information S₄. In Step 15, the control unit 60 controls the opening operation or closing operation of the rear right-side and rear left-side windows.

(Step 16)

The control unit 60 determines whether the condition for unlocking the housing 30 is satisfied. The unlocking condition is, e.g., whether a predetermined period of time has elapsed since the housing 30 was locked. A specific operation such as a double tap or a tracing operation on the detection electrode can be also set as the unlocking condition. The process proceeds to Step 14 when the unlocking condition is satisfied (Step 16: Yes), and the process returns to Step 15 when the unlocking condition is not satisfied (Step 16: No).

(Step 17)

Based on the capacitance value C₂ input from the detection electrode 20L, the control unit 60 determines whether the detection electrode 20L is ON. The control unit 60 can determine whether the detection electrode 20L is ON, by comparing the capacitance value C₂ with the Cth. The process proceeds to Step 18 when the detection electrode 20L is ON (Step 17: Yes), and the process returns to Step 10 when the detection electrode 20L is not ON (Step 17: No).

(Step 18)

Based on the capacitance value C₃ input from the detection electrode 20C, the control unit 60 determines whether the detection electrode 20C is ON. The control unit 60 can determine whether the detection electrode 20C is ON, by comparing the capacitance value C₃ with the Cth. The process proceeds to Step 15 when the detection electrode 20C is ON (Step 18: Yes), and the process proceeds to Step 19 when the detection electrode 20C is not ON (Step 18: No).

(Step 19)

The control unit 60 controls opening/closing of the window of the vehicle via the window regulator by outputting the control signal S₁₀ based on the detection information S₄ about the pull-up operation or push-down operation of the operating knob 10. That is, the operation position is identified by the detection electrode, and an opening operation or a closing operation of the window corresponding to the operation position (driver side, front passenger side, rear right-side, rear left-side) is controlled based on the detection information S₄. In Step 19, the control unit 60 controls the opening operation or closing operation of the rear left-side window.

(Step 20)

The control unit 60 determines whether the condition for unlocking the housing 30 is satisfied. The unlocking condition is, e.g., whether a predetermined period of time has elapsed since the housing 30 was locked. A specific operation such as a double tap or a tracing operation on the detection electrode can be also set as the unlocking condition. The process proceeds to Step 14 when the unlocking condition is satisfied (Step 20: Yes), and the process returns to Step 19 when the unlocking condition is not satisfied (Step 20: No).

The operation of the switch device 1 ends after the above-described series of steps. However, the operation described above can be repeatedly executed as necessary.

### Effects of the Embodiment

(1) The switch device 1 in the present embodiment has the operating knob 10 to receive switch operations for plural devices to be controlled, the detection electrodes (20R, 20C, 20L) as a detection unit attached to the operating knob 10 to detect the operation position on the operating knob 10, the housing 30 displaceably supporting the operating knob 10, and the control unit 60 to control at least one of the plural devices to be controlled in response to the operation position detected by the detection electrodes (20R, 20C, 20L), and it is configured such that the control unit 60 identifies the at least one device to be controlled in response to a displacement state of the operating knob 10. Since the opening/closing operation of the right and left windows on the front and rear sides can be performed by the single operating knob 10, it is possible to further reduce the size of the switch device.

(2) The switch device 1 in the present embodiment can include the detection electrode 20C that detects contact or proximity to the central portion in the direction intersecting the displacement direction of the operation knob. Therefore, it is possible to collectively control the front side (driver side and front passenger side) windows and to collectively control the rear side (rear right-side and rear left-side) windows.

(3) From the above, it is possible to achieve a small window regulator switch with a single knob.

(4) By detecting left and right by the capacitance raised at the operation knob, it is possible to switch between left and right with a single operation knob. This allows space to be saved in terms of the right-left width. In addition, by combining a physical switch with the capacitance, it can be used with an operation feeling close to the conventional feeling of use. By forming the tip of the operation knob in a mountain shape, whether the touching position is left or right can be known by sensation to the finger. These can be done by one finger, hence, a switch device designed in consideration of the way of moving during the operation (in consideration of smartness) is realized.

Although some embodiment and modifications of the invention have been described, these embodiment and modifications are merely examples and the invention according to claims is not to be limited thereto. These new embodiment and modifications may be implemented in various other forms, and various omissions, substitutions and changes, etc., can be made without departing from the gist of the invention. In addition, all combinations of the features described in these embodiment and modifications are not necessary to solve the problem of the invention. Further, these embodiment and modifications are included within the scope and gist of the invention and also within the invention described in the claims and the range of equivalency.

### REFERENCE SIGNS LIST

1 SWITCH DEVICE
10 OPERATING KNOB
10L LEFT END SIDE
10R RIGHT END SIDE
10C CENTRAL PORTION
20R, 20L, 20C DETECTION ELECTRODE
30 HOUSING
33 RECESSED PORTION
35 ROTATING SHAFT
60 CONTROL UNIT
100 VEHICLE
200 FINGER

1. A switch device, comprising:
an operating knob to receive switch operations for a plurality of devices to be controlled;
a detection unit attached to the operating knob to detect an operation position on the operating knob;
a housing displaceably supporting the operating knob; and
a control unit to control at least one of the plurality of devices to be controlled in response to the operation position detected by the detection unit,
wherein the control unit identifies the at least one device to be controlled in response to a displacement state of the operating knob.

2. The switch device according to claim 1, wherein the detection unit comprises sensing portions arranged respectively at a plurality of locations on the single operating knob to detect contact or proximity of a human body.

3. The switch device according to claim 2, wherein the sensing portions are arranged so as to detect contact or proximity to at least both end portions in a direction intersecting a displacement direction of the operating knob.

4. The switch device according to claim 3, wherein the sensing portion is arranged so as to detect contact or proximity to a central portion in the direction intersecting the displacement direction of the operating knob.

5. The switch device according to claim 2, wherein the sensing portion comprises a detection electrode to detect capacitance.

6. The switch device according to claim 1, wherein the switch device is mounted on a vehicle, the position of the operating knob can be moved in a rearward direction of the vehicle, and the control unit controls at least one of the plurality of devices to be controlled in response to the position of the operating knob.

7. The switch device according to claim 6, wherein movement of the operating knob is locked in a state in which the position thereof is moved in the rearward direction of the vehicle.

8. The switch device according to claim 7, wherein the operating knob is unlocked when a predetermined period of time elapses or a predetermined operation is performed on the sensing portion after being locked in a state in which the position thereof is moved in the rearward direction of the vehicle.

9. The switch device according to claim 7, comprising:
a solenoid actuator as a mechanism to lock or unlock movement of the operating knob.

10. The switch device according to claim 4, wherein the control unit controls all the devices to be controlled when contact or proximity to the central portion in the direction intersecting the displacement direction of the operating knob is detected.
